(19) United States
(12) Patent Application Publication
(10) Pub. No.: US 2023/0022582 A1
(43) Pub. Date: Jan. 26, 2023

(54) LIGHT EMITTING ELEMENT AND DISPLAY DEVICE

(71) Applicant: Japan Display Inc., Tokyo (JP)

(72) Inventor: Asami SAKAMOTO, Tokyo (JP)

(73) Assignee: Japan Display Inc., Tokyo (JP)

(21) Appl. No.: 17/952,339

(22) Filed: Sep. 26, 2022

Related U.S. Application Data
(63) Continuation of application No. PCT/JP2021/008200, filed on Mar. 3, 2021.

(30) Foreign Application Priority Data
Apr. 1, 2020 (JP) 2020-065831

(51) Int. Cl. H01L 51/50

(52) U.S. Cl. CPC H01L 51/5004

(57) ABSTRACT

A light emitting element includes a pair of electrodes and first and second organic layers between the pair of electrodes. The second organic layer is adjacent to the first organic layer. The first organic layer includes a first organic material. The second organic layer includes a second organic material. The second organic layer includes a first region and a second region. The first region is in contact with the first organic layer and includes the first organic material.

### CROSS-REFERENCE TO RELATED APPLICATIONS

This application is a Continuation of International Patent Application No. PCT/JP2021/008200, filed on Mar. 3, 2021, which claims the benefit of priority to Japanese Patent Application No. 2020-065831, filed on Apr. 1, 2020, the entire contents of which are incorporated herein by reference.

### FIELD

One embodiment of the present invention relates to a light emitting element and a display device including the light emitting element.

### BACKGROUND

An organic light emitting display device using an organic electroluminescence material (organic EL material) for a light emitting element (organic light emitting element) in a display area is known as a display device. The organic light emitting display device is a so-called self-luminous display device that realizes display by causing the organic EL material to emit light.

The organic light emitting display device has an electroluminescent element (hereinafter referred to as a light emitting element) as a display element in each of a plurality of pixels formed on a substrate. The light emitting element has a layer including an electroluminescent organic compound (hereinafter referred to as a light emitting layer) between a pair of electrodes. By supplying a current between the pair of electrodes, carriers (holes and electrons) are injected from these electrodes into the light emitting layer, and the holes and electrons recombine in the light emitting layer causing them to exhibit an excited state. The function of a display device is exhibited by extracting energy in the process of relaxing the excited state to a ground state as light emission.

a light emitting element of a high-brightness organic light emitting display device having an element structure in which a hole-blocking layer or an electron-blocking layer is provided adjacent to the light emitting layer, or an element sandwiched between the hole-blocking layer and the electron-blocking layer adjacent to the light emitting layer is known (see, for example, JP-A-2000-196140). According to Japanese Patent Application Laid-Open No. 2000-196140, holes and electrons can be effectively confined in the light emitting layer by a hole-blocking layer or an electron-blocking layer adjacent to the light emitting layer so that a light emitting element with high light emitting efficiency can be obtained.

### SUMMARY

A light emitting element includes a pair of electrodes and first and second organic layers between the pair of electrodes. The second organic layer is adjacent to the first organic layer. The first organic layer includes a first organic material. The second organic layer includes a second organic material. The second organic layer includes a first region and a second region. The first region is in contact with the first organic layer and includes the first organic material.

### BRIEF DESCRIPTION OF DRAWINGS

FIG. 1 is a schematic cross-sectional view of a light emitting element according to an embodiment of the present invention.

FIG. 2 is a schematic cross-sectional view of a light emitting element according to an embodiment of the present invention.

FIG. 3 is a schematic cross-sectional view of a light emitting element according to an embodiment of the present invention.

FIG. 4 is a schematic cross-sectional view of a light emitting element according to an embodiment of the present invention.

FIG. 5 is a plan view showing a configuration of a display device according to an embodiment of the present invention.

FIG. 6 is a cross-sectional view showing a configuration of a display device according to an embodiment of the present invention.

FIG. 7 is a plan view showing a layout of a plurality of pixels arranged in a matrix in the display area of a display device according to an embodiment of the present invention.

FIG. 8 is a cross-sectional view of a display area of a display device according to an embodiment of the present invention.

### DESCRIPTION OF EMBODIMENTS

When a hole blocking layer or an electron blocking layer is provided adjacent to a light emitting layer, carriers accumulate too much at the interface between the light emitting layer and the hole blocking layer or at the interface between the light emitting layer and the electron blocking layer. As a result, oxidation or reduction reactions that do not contribute to luminescence could occur at the interface. Therefore, although the luminous efficiency of the light emitting element is improved, it is difficult to sufficiently secure the reliability of the light emitting element because of the oxidation or reduction reactions.

In view of the above problem, one object of an embodiment of the present invention is to provide a light emitting element and a display device with improved reliability.

Each embodiment of the present invention is described below while referring to the drawings. However, the present invention can be implemented in various modes without departing from the gist of the invention and should not be interpreted as being limited to the description of the embodiments exemplified below.

Although the drawings may be schematically represented in terms of width, thickness, shape, and the like of each part as compared with their actual mode in order to make explanation clearer, it is only an example and an interpretation of the present invention is not limited. In addition, in the drawings, the same reference numerals are provided to the same elements as those described previously with reference to preceding figures and repeated explanations may be omitted accordingly.

In the case when a single film is processed to form a plurality of structural bodies, each structural body may have different functions and roles, and the bases formed beneath each structural body may also be different. However, the plurality of structural bodies is derived from films formed in the same layer by the same process and have the same material. Therefore, the plurality of these films is defined as existing in the same layer.

When expressing a mode in which another structure is arranged over a certain structure, in the case where it is simply described as “over”, unless otherwise noted, a case where another structure is arranged directly over a certain structure as if in contact with that structure, and a case where another structure is arranged via another structure over a certain structure, are both included.

The phrase “a structure is exposed from another structure” means an area where a portion of a structure is not covered by another structure. However, it also includes the case where the part not covered by the other structure is further covered by another structure.

### First Embodiment

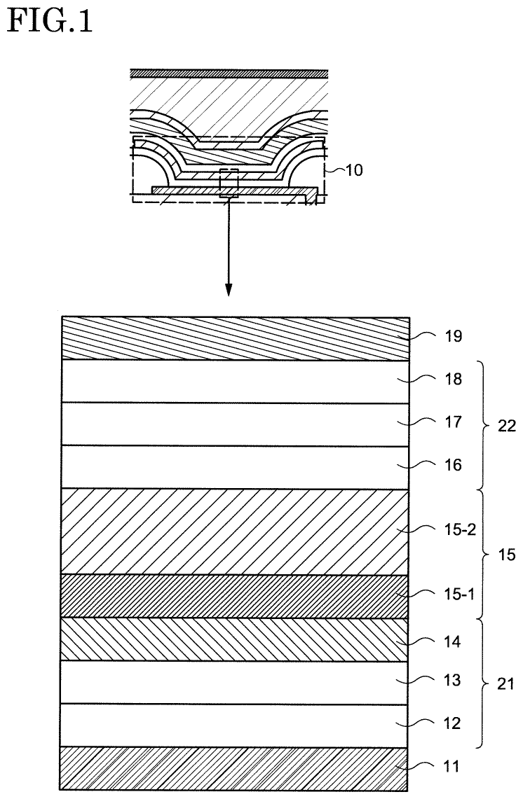

A configuration of a light emitting element 10 according to an embodiment of the present invention is described with reference to FIG. 1.

FIG. 1 is a schematic cross-sectional view of a light emitting element 10 according to an embodiment of the present invention. Specifically, FIG. 1 shows an enlarged cross-sectional view of a part of a light emitting element 10 provided in a display area of a display device. Details of the display device are described later.

The light emitting element 10 includes a pair of electrodes (a first electrode 11 and a second electrode 19), a first organic layer 14, and a second organic layer 15. The first organic layer 14 and the second organic layer 15 are provided between the pair of electrodes (the first electrode 11 and the second electrode 19). The second organic layer 15 is provided adjacent to the first organic layer 14. The second organic layer 15 includes a first region 15-1 and a second region 15-2, and the first region 15-1 is in contact with the first organic layer 14. The light emitting element 10 further includes a third organic layer 16 adjacent to the second organic layer 15 between the pair of electrodes (the first electrode 11 and the second electrode 19). The second region 15-2 is in contact with the third organic layer 16.

For example, the first electrode 11 is an anode, the first organic layer 14 is an electron blocking layer, the second organic layer 15 is a light emitting layer, the third organic layer 16 is a hole blocking layer, and the second electrode 19 is a cathode. In this case, as shown in FIG. 1, the light emitting element 10 can include the first electrode 11 (the anode), a hole injection layer 12, a hole transporting layer 13, the first organic layer 14 (the electron blocking layer), the second organic layer 15 (the light emitting layer), the third organic layer 16 (the hole blocking layer), an electron transporting layer 17, an electron injection layer 18, and the second electrode 19 (the cathode). However, the configuration of the light emitting element 10 is not limited to this. The hole injection layer 12, the hole transporting layer 13, the electron transporting layer 17, or the electron injection layer 18 can be provided as appropriate.

Further, as another example, the first electrode 11 is a cathode, the first organic layer 14 is a hole blocking layer, the second organic layer 15 is a light emitting layer, the third organic layer 16 is an electron blocking layer, the third organic layer 16 is an electron blocking layer, and the second electrode 19 is an anode. Also in this case, a hole injection layer, a hole transporting layer, an electron transporting layer, or an electron injection layer can be provided as appropriate.

In the following description, for easy understanding of the present embodiment, the first electrode 11, the first organic layer 14, the second organic layer 15, the third organic layer 16, and the second electrode 19 are described as an anode, an electron blocking layer, a light emitting layer, a hole blocking layer, and a cathode, respectively. Further, hereinafter, a layer between the first electrode 11 and the second organic layer 15 may be described as a first functional layer 21, and a layer between the second organic layer 15 and the second electrode 19 may be described as a second functional layer 22.

### [Electron Blocking Layer]

The first organic layer 14 can function as an electron blocking layer. That is, the first organic layer 14 can prevent electrons injected from the second electrode 19 into the second functional layer 22 from passing through the second organic layer 15 to the hole transporting layer 13 without contributing to recombination. In other words, the first organic layer 14 can confine electrons in the second organic layer 15 and prevent the excitation energy of recombination obtained in the second organic layer 15 from being transferred to the hole transporting layer 13. Therefore, it is preferable that the first organic layer 14 has a higher hole transporting property than an electron transporting property. Further, the absolute value of the lowest unoccupied molecular orbital (LUMO) level of the first organic layer 14 is preferably smaller than the absolute value of the lowest unoccupied molecular orbital (LUMO) level of the second organic layer 15. Specifically, the absolute value of the difference between the LUMO level of the first organic layer 14 and the LUMO level of the second organic layer 15 is greater than or equal to 0.2 eV, preferably greater than or equal to 0.3 eV, and more preferably greater than or equal to 0.5 eV.

In addition, the band gap of the first organic layer 14 is preferably larger than the band gap of the second organic layer 15.

The first organic layer 14 includes a first organic material. The first organic material is a material that has a higher hole transporting property than an electron transporting property. For example, a carbazole derivative, an arylamine derivative, or a thiophene derivative having a relatively small conjugated system can be used as the first organic material.

### [Light Emitting Layer]

The second organic layer 15 can function as a light emitting layer. That is, the second organic layer 15 is a layer in which holes and electrons recombine. The second organic layer 15 has a host-guest type configuration. In other words, the second organic layer 15 includes a second organic material as a host material and a light emitting material as a guest material. For example, condensed aromatic compounds such as stilbene derivatives or anthracene derivatives, carbazole derivatives, metal complexes containing quinolinol ligands, aromatic amines, nitrogen-containing heteroaromatic compounds such as phenanthroline derivatives, and the like can be used as the second organic material. For example, a fluorescent material such as a coumarin derivative, a pyran derivative, a quinocridone derivative, a tetracene derivative, a pyrene derivative, or an anthracene derivative, or a phosphorescent material such as an iridium-based orthometal complex can be used as the light emitting material. The second organic layer 15 is configured such that the bandgap of the second organic material is larger than the bandgap of the light emitting material.

The second organic layer 15 of the light emitting element 10 according to the present embodiment further includes a first organic material. By adding the first organic material having a higher hole transporting property than an electron transporting property to the second organic layer 15, the hole transporting property of the second organic layer 15 can be improved. In other words, the first organic material can be used to adjust the hole transporting property and the electron transporting property of the second organic layer 15 (adjustment of carrier balance).

In general, the second organic material of the second organic layer 15 has a higher electron transporting property than a hole transporting property. Therefore, the carriers in the second organic layer 15 are predominantly electrons rather than holes, and electrons tend to accumulate at the interface between the first organic layer 14 and the second organic layer 15. In this case, the light emitting region is in the vicinity of the interface, and concentration quenching is likely to occur due to the high electron density at the interface. That is, since carriers that do not contribute to increases in light emission, the current efficiency of the display element decreases.

On the other hand, when the first organic material is added to the second organic layer 15, the hole transporting property of the second organic layer 15 is enhanced. Since the number of holes that recombine with electrons increases in the second organic layer 15, the number of electrons reaching the interface between the first organic layer 14 and the second organic layer 15 can be reduced. Therefore, since the light emitting region expands over the entire second organic layer 15, the current efficiency of the light emitting element 10 is improved.

Further, the second organic layer 15 includes a first region 15-1 and a second region 15-2. The first region 15-1 is in contact with the first organic layer 14. The second region 15-2 is away from the first organic layer 14.

The concentration of the first organic material is different between the first region 15-1 and the second region 15-2. The concentration of the first organic material in the first region 15-1 is preferably larger than the concentration of the first organic material in the second region 15-2. For example, the concentration of the first organic material in the first region 15-1 is less than or equal to 20% by weight, preferably less than or equal to 15% by weight, and more preferably less than or equal to 10% by weight. Further, the concentration of the first organic material in the second region 15-2 is smaller than the concentration of the first organic material in the first region 15-1, and is less than or equal to 15% by weight, preferably less than or equal to 10% by weight, and more preferably less than or equal to 5% by weight. When the concentration of the first organic material in the second region 15-2 is large, holes accumulate at the interface between the third organic layer 16 and the second organic layer 15. Therefore, the concentration of the first organic material in each of the first region 15-1 and the second region 15-2 is adjusted within the above range, and the hole transporting properties in the first region 15-1 and the second region 15-2 are preferably adjusted.

Further, the first region 15-1 and the second region 15-2 may have different film thicknesses. The film thickness of the first region 15-1 is preferably smaller than the film thickness of the second region 15-2. For example, the film thickness of the first region 15-1 is larger than 0% of the film thickness of the second organic layer 15 and is less than or equal to 40%, preferably less than or equal to 30%, and more preferably less than or equal to 20%. The hole transport property of the second organic layer 15 can also be adjusted by adjusting the film thickness of the first region 15-1 within the above range.

By dividing the second organic layer 15 into the first region 15-1 and the second region 15-2, not only the carrier balance can be adjusted, but also the position of the light emitting region can be adjusted. That is, the light emitting region can be away from the interface between the first organic layer 14 and the second organic layer 15. Therefore, the chemical reaction at the interface is suppressed, and the reliability of the light emitting element 10 is improved.

### [Hole Blocking Layer]

The third organic layer 16 can function as a hole blocking layer. That is, the third organic layer 16 can prevent holes injected from the first electrode 11 into the first functional layer 21 from passing through the second organic layer 15 without contributing to recombination. In other words, the third organic layer 16 can confine holes in the second organic layer 15 and prevent the excitation energy of recombination obtained in the second organic layer 15 from being transferred to the electron transporting layer 17. Therefore, it is preferable that the third organic layer 16 has a higher electron transporting property than a hole-transporting property. Further, the absolute value of the highest occupied molecular orbital (HOMO) level of the third organic layer 16 is preferably larger than the absolute value of the highest occupied molecular orbital (HOMO) level of the second organic layer 15. Specifically, the absolute value of the difference between the HOMO level of the third organic layer 16 and the HOMO level of the second organic layer 15 is greater than or equal to 0.2 eV, preferably greater than or equal to 0.3 eV, and more preferably greater than or equal to 0.5 eV.

In addition, the bandgap of the third organic layer 16 is preferably larger than the bandgap of the second organic layer 15.

The third organic layer 16 includes a third organic material. For example, phenanthroline derivatives, oxadiazole derivatives, triazole derivatives, or bis(2-methyl-8-quinolinolato)(4-hydroxy-biphenylyl)aluminum can be used as the third organic material.

### [Anode and Cathode]

The first electrode 11 can function as an anode. That is, the first electrode 11 can inject holes into the first functional layer 21. Therefore, it is preferable to use a material having a large work function for the first electrode 11.

The second electrode 19 can function as a cathode. That is, the second electrode 19 can supply electrons to the second functional layer 22. Therefore, it is preferable to use a material having a small work function for the second electrode 19.

At least one of the first electrode 11 and the second electrode 19 includes a transparent conductive material through which light from the second organic layer 15 can pass. For example, indium tin oxide (ITO), indium zinc oxide (IZO), zinc oxide (ZnO), aluminum zinc oxide (AZO), gallium zinc oxide (GZO), and aluminum zinc oxide (AZO) can be used as the transparent conductive material. Further, when the resistance of the transparent conductive material is high, a stacked structure in which a metal thin film of about several nanometers is sandwiched between transparent conductive materials can be used as the first electrode 11 or the second electrode 19. For example, gold (Au), silver (Ag), copper (Cu), aluminum (Al), tungsten (W), molybdenum (Mo), zinc (Zn), or alloys thereof can be used as the metal thin film.

On the other hand, when reflecting the light from the second organic layer 15, a metal material can be used as the first electrode 11 or the second electrode. For example, gold (Au), silver (Ag), copper (Cu), aluminum (Al), tungsten (W), molybdenum (Mo), zinc (Zn), or an alloy thereof is used as the metal material.

### [Hole Injection Layer]

The hole injection layer 12 has a function of facilitating the injection of holes from the first electrode 11 to the first functional layer 21. The hole injection layer 12 can be made of an easily oxidizable compound (electron donating compound), that is, a compound with a small absolute value of the highest occupied molecular orbital (HOMO) level. For example, aromatic amines such as benzidine derivatives or triarylamines, carbazole derivatives, thiophene derivatives, or phthalocyanine derivatives such as copper phthalocyanine can be used as a material of the hole injection layer 12. Further, for example, polythiophene or polyaniline derivatives can be used as the material of the hole injection layer 12. Furthermore, for example, a mixture of an electron donating compound such as an aromatic amine, a carbazole derivative, or an aromatic hydrocarbon and an electron acceptor may be used as the material for the hole injection layer 12. For example, transition metal oxides such as vanadium oxide and molybdenum oxide, nitrogen-containing heteroaromatic compounds, and heteroaromatic compounds having a strong electron-withdrawing group such as a cyano group can be used as the electron acceptor. Since these materials or mixtures have a low ionization potential, the hole injection barrier from the first electrode 11 is small. Therefore, the hole injection layer 12 contributes to a reduction of the driving voltage of the light emitting element 10.

### [Hole Transporting Layer]

The hole transporting layer 13 has a function of transporting holes injected from the first electrode 11 into the hole injection layer 12 to the second organic layer 15. Materials identical to or similar to the materials that can be used in the hole injection layer 12 can be used for the hole transporting layer 13. Although the absolute value of the HOMO level of the hole transporting layer 13 is preferably smaller than the absolute value of the HOMO level of the hole injection layer 12, the difference is preferably small. That is, the difference between the HOMO level of the hole transporting layer 13 and the HOMO level of the hole injection layer 12 is less than or equal to 0.5 eV, preferably less than or equal to 0.3 eV, and more preferably less than or equal to 0.3 eV. Since the above materials have higher hole transporting properties than electron transporting properties, holes can be efficiently transported to the second organic layer 15, and a low driving voltage for the light emitting element 10 can be realized.

### [Electron Transporting Layer]

The electron transporting layer 17 has a function of transporting electrons injected from the second electrode 19 into the electron injection layer 18 to the second organic layer 15. Compounds having a higher electron transporting property than a hole transporting property can be used for the electron transporting layer 17. For example, metal complexes containing ligands having 8-quinolinol as a basic skeleton, oxadiazole derivatives or triazole derivatives, nitrogen-containing heteroaromatic compounds such as phenanthroline derivatives, silacyclopentadiene derivatives, aromatic hydrocarbons such as anthracene derivatives, pyrene derivatives, or perylene derivatives can be used as a material for the electron transporting layer 17. For example, tris(8-quinolinolato)aluminum (Alq) or (8-quinolinolato)lithium can be used as the metal complexes.

### [Electron Injection Layer]

The electron injection layer 18 has a function of facilitating injection of electrons from the second electrode 19 to the second functional layer 22. For example, a metal fluoride such as calcium fluoride or lithium fluoride, a Group 1 metal or a Group 2 element such as lithium, calcium, or magnesium can be used as a material of the electron injection layer 18. Further, a mixture of the material that can be used for the electron transporting layer 17 and an electron donor may be used for the electron injection layer 18. For example, a group 1 metal or group 2 element, or a lanthanide metal such as ytterbium can be used for the electron donor.

### Specific Example

A typical display device having a stacked structure of an anode, a hole injection layer, a hole transporting layer, an electron blocking layer, a light emitting layer, a hole blocking layer, an electron transporting layer, an electron injection layer, and a cathode was fabricated. Element 1 has a single light emitting layer, and is an element in which the light emitting layer only includes the second organic material and the light emitting material. Element 2 has a single light emitting layer, and is an element in which the light emitting layer includes the first organic material of the electron blocking layer of 10% by weight to the second organic material in addition to the second organic material and the light emitting material. Element 3 has the light emitting layer having two regions (a first region and a second region), and is an element in which the first region in contact with the electron blocking layer includes the first organic material of 10% by weight to the second organic material in addition to the second organic material and the light emitting material and the second region away from the electron blocking layer includes the first organic material of 5% by weight to the second organic material in addition to the second organic material and the light emitting material.

In the Elements 1 to 3, the reliability was evaluated by the current efficiency and the time (LT₉₅) when the brightness reaches 95% from the initial brightness. Table 1 shows the measurement results. In Table 1, the current efficiency and LT₉₅ are normalized by the value of the Element 1.

As can be seen from Table 1, although the current efficiencies of the Elements 1 to 3 are almost the same, the reliabilities of the Elements 1, 2 and 3 are improved in this order. In particular, the improvement in reliability of the Element 3, in which the second organic material is added to the entire light emitting layer and the concentration of the second organic material is increased in the first region in contact with the electron blocking layer, is remarkable.

TABLE 1

| | Element 1 | Element 2 | Element 3 |
|---|---|---|---|
| current | 1.00 | 0.98 | 1.02 |
| efficiency | | | |
| (a.u.) | | | |
| LT₉₅ | 1.00 | 1.17 | 1.42 |
| (a.u.) | | | |

As described above, in the light emitting element 10 according to the present embodiment, by adding the first organic material of the first organic layer 14 functioning as an electron blocking layer into the second organic layer 15 functioning as a light emitting layer, the carrier balance of the second organic layer 15 can be adjusted. In addition, by suppressing the accumulation of electrons at the interface between the first organic layer 14 and the second organic layer 15 and keeping the light emitting region away from the interface between the first organic layer 14 and the second organic layer 15, the current efficiency and reliability of the light emitting element 10 are improved.

### <Modification 1>

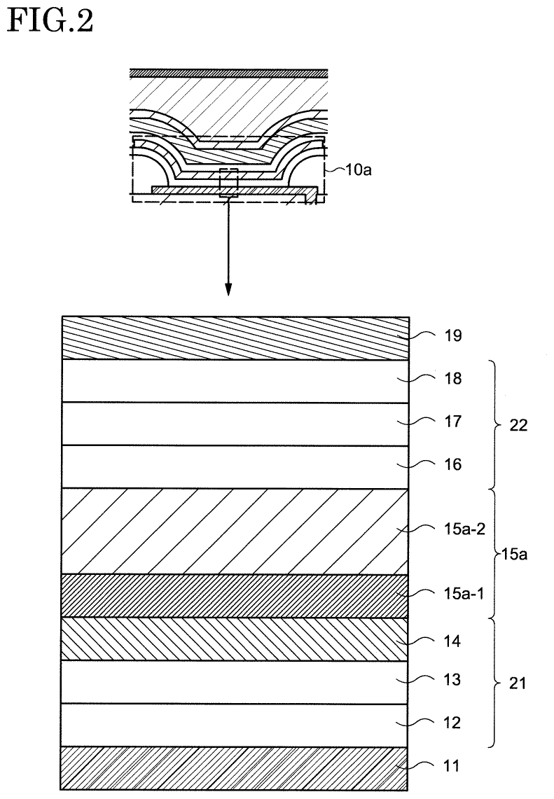

A configuration of a light emitting element 10a according to another embodiment of the light emitting element 10 is described with reference to FIG. 2. In the following description, descriptions of configurations similar to those of the light emitting element 10 are omitted, and configurations different from those of the light emitting element 10 are mainly described.

FIG. 2 is a schematic cross-sectional view of a light emitting element 10a according to an embodiment of the present invention. Specifically, FIG. 2 shows an enlarged cross-sectional view of a part of the light emitting element 10a provided in the display area of the display device. Details of the display device are described later.

The light emitting element 10a includes the pair of electrodes (the first electrode 11 and the second electrode 19), the first organic layer 14, and a second organic layer 15a. The first organic layer 14 and the second organic layer 15a are provided between the pair of electrodes (the first electrode 11 and the second electrode 19). The second organic layer 15a is provided adjacent to the first organic layer 14. The second organic layer 15a includes a first region 15a-1 and a second region 15a-2, and the first region 15a-1 is in contact with the first organic layer. The first organic layer 14 includes the first organic material and the second organic layer 15a includes the second organic material.

In the light emitting element 10a, although the first region 15a-1 includes the first organic material, the second region 15a-2 does not include the first organic material. That is, in the light emitting element 10a, the carrier balance in the second organic layer 15a can be adjusted by the concentration and film thickness of the first organic material in the first region 15a-1. Therefore, the current efficiency and reliability are improved in the light emitting element 10a as well.

### <Modification 2>

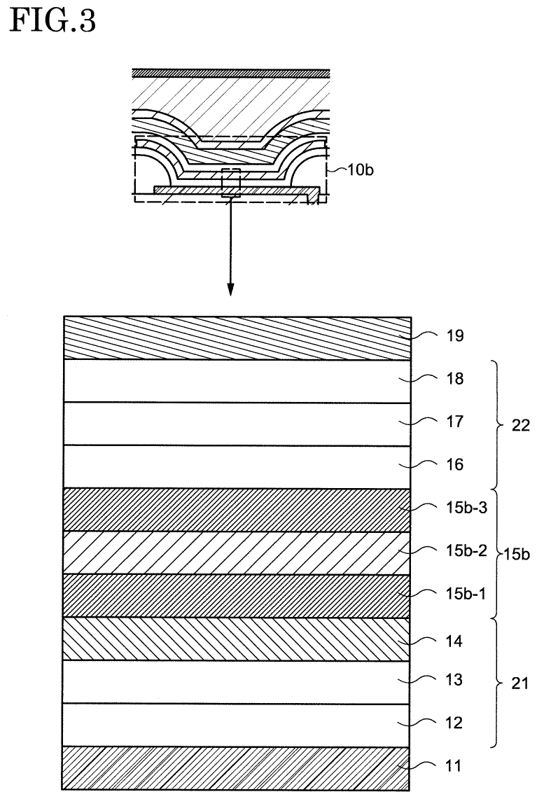

A configuration of a light emitting element 10b according to another embodiment of the light emitting element 10 is described with reference to FIG. 3. In the following description, descriptions of configurations similar to those of the light emitting element 10 are omitted, and configurations different from those of the light emitting element 10 are mainly described.

FIG. 3 is a schematic cross-sectional view of a light emitting element 10b according to an embodiment of the present invention. Specifically, FIG. 3 shows an enlarged cross-sectional view of a part of the light emitting element 10b provided in the display area of the display device. Details of the display device are described later.

The light emitting element 10b includes the pair of electrodes (the first electrode 11 and the second electrode 19), the first organic layer 14, and a second organic layer 15b. The first organic layer 14 and the second organic layer 15b are provided between the pair of electrodes (the first electrode 11 and the second electrode 19). The second organic layer 15b is provided adjacent to the first organic layer 14. The second organic layer 15b includes a first region 15b-1, a second region 15b-2, and a third region 15b-3, and the first region 15b-1 is in contact with the first organic layer. The third region 15b-3 is farther from the first organic layer 14 than the second region 15b-2. The first organic layer 14 includes the first organic material and the second organic layer 15b includes the second organic material.

In the light emitting element 10b, each of the first region 15b-1, the second region 15b-2, and the third region 15b-3 includes the first organic material. The concentration of the first organic material in the first region 15b-1 is larger than the concentration of the first organic material in the third region 15b-3. Further, the concentration of the first organic material in the second region 15b-2 is larger than the concentration of the first organic material in the third region 15b-3 and smaller than the concentration of the first organic material in the first region 15b-1.

In the light emitting element 10b, the carrier balance in the second organic layer 15b can be adjusted by adjusting the concentration and thickness of the first organic material in each of the first region 15b-1, the second region 15b-2, and the third region 15b-3. Therefore, the current efficiency and reliability are improved in the light emitting element 10b as well.

In the present embodiment, the three regions such as the first region 15b-1, the second region 15b-2, and the third region 15b-3 each having the different concentration of the first organic material in the second organic layer 15 is described. However, the number of regions with different concentrations of the first organic material may be three or more. Alternatively, the second organic layer 15 may be continuously provided such that the concentration of the first organic material decreases from the first organic layer 14 toward the third organic layer 16.

### Second Embodiment

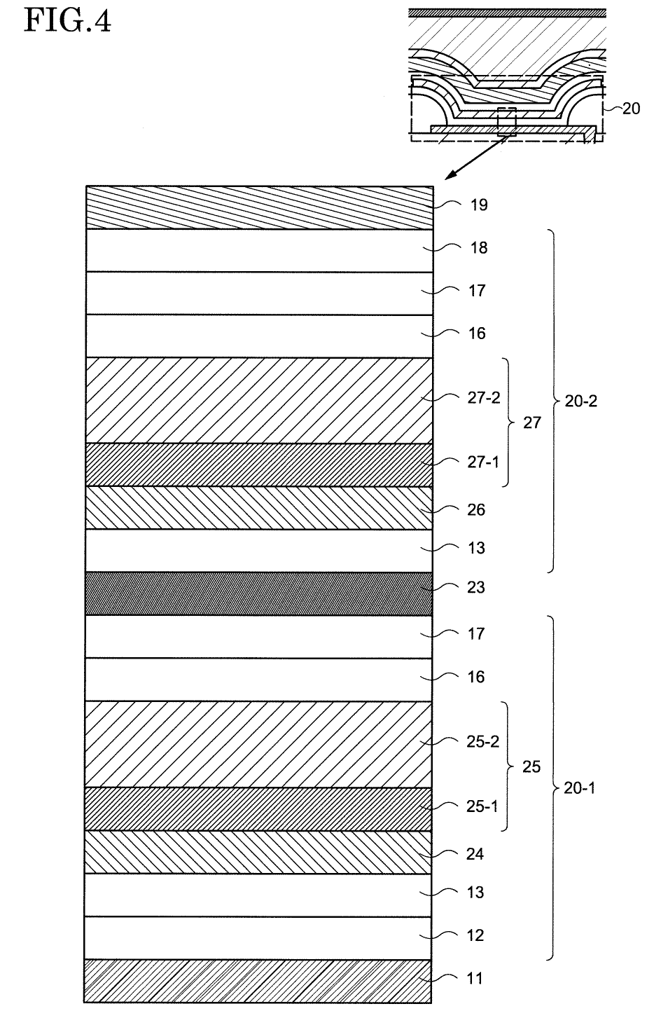

A configuration of a light emitting element 20 according to an embodiment of the present invention is described with reference to FIG. 4. In the following description, descriptions of configurations similar to those of the light emitting element 10 are omitted, and configurations different from those of the light emitting element 10 are mainly described.

FIG. 4 is a schematic cross-sectional view of a light emitting element 20 according to an embodiment of the present invention. Specifically, FIG. 4 shows an enlarged cross-sectional view of a part of the light emitting element 20 provided in the display area of the display device. Details of the display device are described later.

The light emitting element 20 includes the pair of electrodes (the first electrode 11 and the second electrode 19), a first unit 20-1, a second unit 20-2, and a charge generating layer 23. The first unit 20-1, second unit 20-2, and charge generation layer 23 are provided between the pair of electrodes (the first electrode 11 and the second electrode 19). The charge generation layer 23 is provided between the first unit 20-1 and the second unit 20-2.

The first unit 20-1 includes a first organic layer 24 and a second organic layer 25. The second organic layer 25 includes a first region 25-1 and a second region 25-2, and the first region 25-1 is in contact with the first organic layer 24. Further, the second unit 20-2 includes a first organic layer 26 and a second organic layer 27. The second organic layer 27 includes a first region 27-1 and a second region 27-2, and the first region 27-1 is in contact with the first organic layer 26. The first organic layer 24 of the first unit 20-1 includes the first organic material and the second organic layer 25 includes the second organic material. Further, the first organic layer 26 of the second unit includes the first organic material, and the second organic layer 27 includes the second organic material. The first organic material and the second organic material are described in the First Embodiment. The first organic material of the first unit 20-1 and the first organic material of the second unit 20-2 may be the same or may be different from each other. Similarly, the second organic material of the first unit 20-1 and the second organic material of the second unit 20-2 may be the same or different from each other.

In the Second Embodiment, as in the First Embodiment, the second organic layer 25 of the first unit 20-1 includes the first organic material of the first organic layer 24, and the second organic layer 27 of the second unit 20-2 includes the first organic material of first organic layer 26.

In the following description, for easy understanding of the present embodiment, the first electrode 11, the first organic layer, the second organic layer 15, the third organic layer 16, and the second electrode 19 are described as an anode, an electron blocking layer, a light emitting layer, a hole blocking layer, and a cathode, respectively.

The first unit 20-1 further includes the hole injection layer 12, the hole transporting layer 13, the third organic layer 16 (the hole blocking layer), and the electron transporting layer 17. The second unit 20-2 further includes the hole transporting layer 13, a third organic layer 16 (the hole blocking layer), the electron transporting layer 17, and an electron injection layer 18. However, the configuration of the light emitting element 20 is not limited to this. Layers included in the first unit 20-1 and the second unit 20-2 can be provided or omitted as appropriate.

When a voltage is applied between the first electrode 11 and the second electrode 19, the charge generation layer 23 has a function for injecting electrons into the first unit 20-1 and injecting holes into the second unit 20-2. The charge generation layer 23 is a mixture of the material identical to or similar to that used in the hole transporting layer 13 and an electron acceptor, or a mixture of the material identical to or similar to that used in the electron transporting layer 17 and an electron donor.

As described above, in the light emitting element 20 according to the present embodiment, since light emission is obtained from the first unit 20-1 and the second unit 20-2, the light emitting element has high current efficiency and high reliability. By adding the first organic material of the first organic layers 24 and 26 functioning as electron blocking layers into the second organic layers 25 and 27 functioning as light emitting layers, respectively, the carrier balance of the second organic layers 25 and 27 can be adjusted. In addition, by suppressing the accumulation of electrons at the interface between the first organic layer 24 and the second organic layer 25 and the interface between the first organic layer 26 and the second organic layer 27, and keeping the light emitting region away from the interface between the first organic layer 14 and the second organic layer 15 and the interface between the first organic layer 26 and the second organic layer 27, the current efficiency and reliability of the light emitting element 20 are further improved.

### Third Embodiment

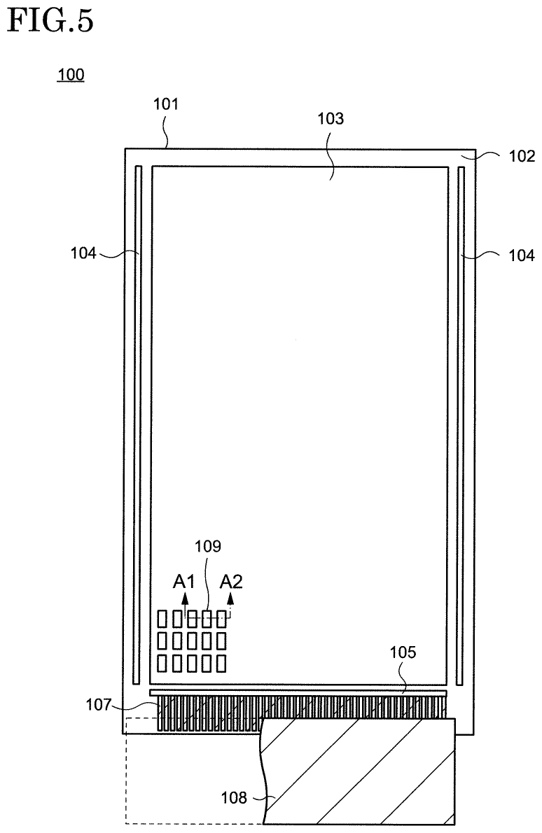

A configuration of a display device 100 according to an embodiment of the present invention is described with reference to FIGS. 5 to 8.

FIG. 5 is a plan view showing a configuration of a display device 100 according to an embodiment of the present invention. The display device 100 includes a substrate 101, a peripheral area 102, and a display area 103.

The display area 103 is provided on the substrate 101. The display area 103 includes a plurality of pixels 109. The plurality of pixels 109 are arranged in a matrix. The number of arrays of the plurality of pixels 109 is arbitrary. For example, m pixels 109 are arranged in the row direction and n pixels 109 in the column direction (m and n are integers). Each of the plurality of pixels 109 includes a pixel circuit having at least a selection transistor, a drive transistor, and a light emitting element (not shown in FIG. 5).

A peripheral area 102 is provided so as to surround the display area 103. The peripheral area 102 refers to an area from the display area 103 to the edge of the substrate 101. In other words, the peripheral area 102 refers to a region other than the display area 103 provided on the substrate 101 (that is, a region outside the display area 103). The peripheral area 102 includes drive circuits 104 and terminals 107. The drive circuits 104 are provided so as to sandwich the display area 103. A driver IC 105 may be provided in the peripheral area 102. The driver IC 105 is connected to terminals 107. The terminals 107 are connected to a flexible printed circuit 108 (FPC).

The driver circuit 104 is connected to a scanning line that is connected to the pixel 109 and functions as a scanning line driver circuit. Further, the driver IC 105 is connected to a signal line that is connected to the pixel 109, and incorporates a signal line driving circuit. Although FIG. 5 shows the configuration in which the signal line driving circuit is incorporated in the driver IC 105, the signal line driving circuit may be provided on the substrate 101 separately from the driver IC 105.

The driver IC 105 is arranged on the substrate 101 in the form of an IC chip. Further, the driver IC 105 may be provided on the flexible printed circuit 108 (not shown in FIG. 5).

A video signal is applied to each of the plurality of pixels 109 from the driver IC 105 via a signal line. Further, each pixel 109 is supplied with a signal for selecting each pixel 109 from the driver IC 105 via the driving circuit 104 and the scanning line. A transistor included in the pixel 109 can be driven by these signals, so that screen display can be performed according to the video signal.

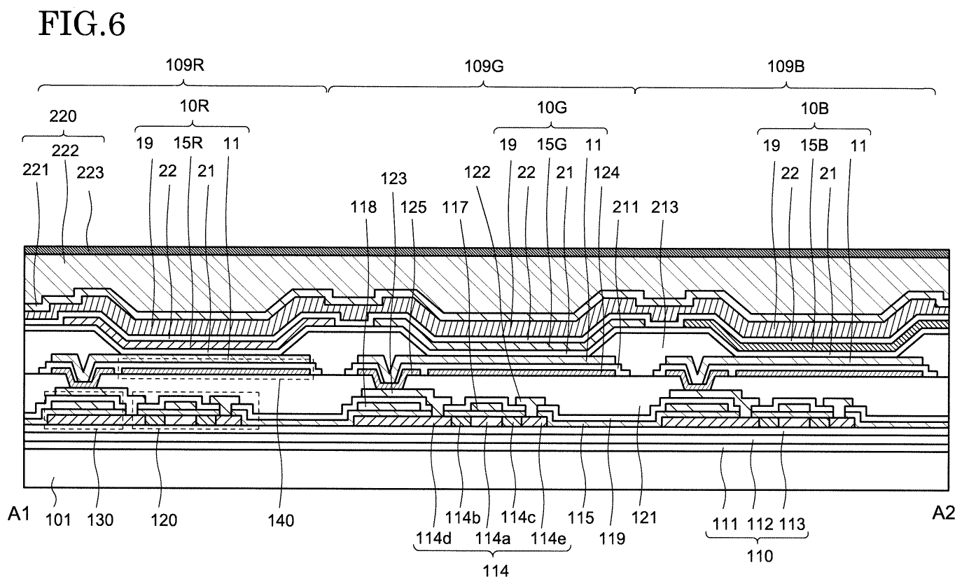

FIG. 6 is a cross-sectional view showing a configuration of the display device 100 according to an embodiment of the present invention. Specifically, FIG. 6 is a cross-sectional view of the display device 100 cut along a line A1-A2 shown in FIG. 5.

As shown in FIG. 6, the display area 103 includes a plurality of pixels 109R, 109G, and 109B. In FIG. 6, the light emitting elements 10R, 10G, and 10B included in each of the plurality of pixels 109R, 109G, and 109B are distinguished by their emission colors. For example, the light emitting element 10R of the pixel 109R emits red light, the light emitting element 10G of the pixel 109G emits green light, and the light emitting element 10B of the pixel 109B emits blue light.

A transistor 120 and a capacitor 130 are provided over the substrate 101 via a base layer 110.

A glass substrate, a quartz substrate, or a flexible substrate (polyimide, polyethylene terephthalate, polyethylene naphthalate, triacetyl cellulose, cyclic olefin copolymer, cycloolefin polymer, and other flexible resin substrates) can be used as the substrate 101. When the substrate 101 does not need to be translucent, a metal substrate, a ceramic substrate, or a semiconductor substrate can be used as the substrate 101. When the flexible substrate is used as the substrate 101, the display device 100 can be bent.

The base layer 110 is provided on the substrate 101. The base layer 110 is an insulating layer including an inorganic material such as silicon oxide, silicon nitride, or aluminum oxide. The base layer 110 may have a single-layer structure, or may have, for example, a stacked structure in which a silicon oxide layer and a silicon nitride layer are combined. In the embodiment, the case where the base layer 110 is provided with a three-layer structure of a silicon nitride layer 111, a silicon oxide layer 112, and a silicon nitride layer 113 is shown. The configuration may be appropriately determined in consideration of adhesion to the substrate 101 and gas barrier properties with respect to the transistor 120.

The transistor 120 includes a semiconductor layer 114, a gate insulating film 115, a gate electrode 117, a source electrode 122, or a drain electrode 123. The transistor 120 may be an N-ch type transistor or a P-ch type transistor. In the embodiment, the case where the transistor 120 uses an N-ch type transistor is described.

Amorphous, polysilicon, or an oxide semiconductor can be used for the semiconductor layer 114. In the embodiment, the case of using polysilicon is described. The N-ch type transistor has a structure in which low-concentration impurity regions 114b and 114c are provided between a channel region 114a and high-concentration impurity regions 114d and 114e (source and drain regions) in the semiconductor layer 114.

An insulating layer including an inorganic material such as silicon oxide, silicon nitride, or aluminum oxide can be used as the gate insulating film 115. A conductive layer including a metal material such as copper, molybdenum, tantalum, tungsten, or aluminum can be used as the gate electrode 117. A conductive layer including a metal material such as copper, titanium, molybdenum, or aluminum can be used as each of a source electrode 122 and a drain electrode 123.

The capacitor 130 is formed of a pair of electrodes with the gate insulating film 115 interposed therebetween. The high concentration impurity region 114d of the semiconductor layer 114 is used for one electrode of the capacitor 130, and the conductive layer 118 is used for the other electrode of the capacitor 130. The conductive layer 118 is formed from the same film as the gate electrode 117.

An interlayer insulating layer 119 is provided to cover the transistor 120 and the capacitor 130. The interlayer insulating layer 119 is an insulating layer including an inorganic material such as silicon oxide, silicon nitride, or aluminum oxide. The source electrode 122 and the drain electrode 123 are provided over the interlayer insulating layer 119. The source electrode 122 or drain electrode 123 is connected to the semiconductor layer 114 (high concentration impurity regions 114d and 114e) through contact holes provided in the gate insulating film 115 and the interlayer insulating layer 119.

A planarizing film 121 is provided on the interlayer insulating layer 119. The planarizing film 121 includes an organic resin material. For example, an organic material such as polyimide, polyamide, acrylic, or epoxy can be used as the organic resin material. These materials can be formed into a film by a solution coating method, and are characterized by a high leveling effect. The planarizing film 121 includes a contact hole that exposes a part of the source electrode 122 or the drain electrode 123. The contact hole is provided to electrically connect the first electrode 11 and the source electrode 122 or the drain electrode 123.

A transparent conductive layer 125 is provided in the contact hole provided in the planarizing film 121. The transparent conductive layer 125 overlaps the contact hole of the planarizing film 121 and is electrically connected to the source electrode 122 or the drain electrode 123 exposed at the bottom of the contact hole. An indium oxide-based transparent conductive layer (e.g., ITO) or a zinc oxide-based transparent conductive layer (e.g., IZO or ZnO) can be used as the transparent conductive layer 125. A transparent conductive layer 124 is provided on the planarizing film 121. The transparent conductive layer 125 and the transparent conductive layer 124 are made of the same material.

Further, an insulating layer 211 is provided on the transparent conductive layer 125. A silicon nitride layer or the like is preferably used as the insulating layer 211. A contact hole is formed in the insulating layer 211 in a region where the source electrode 122 or the drain electrode 123 and the transparent conductive layer 125 overlap.

Furthermore, the first electrode 11 is provided on the insulating layer 211. The first electrode 11 is connected to the transparent conductive layer 125 through a contact hole provided in the insulating layer 211. Thereby, the first electrode 11 is electrically connected to the source electrode 122 or drain electrode 123. In addition, the capacitor 130 is formed of the first electrode 11, the insulating layer 211, and the transparent conductive layer 124.

The light emitting elements 10R, 10G, and 10B are provided on the insulating layer 211. The light emitting elements 10R, 10G, and 10B each include the first electrode 11, the first functional layer 21, the second functional layer 22, and the second electrode 19. The light emitting elements 10R, 10G, and 10B also include the second organic layers 15R, 15G, and 15B, respectively, according to the colors of light emission. Banks 213 are provided to separate the light emitting elements 10R, 10G, and 10B from each other. The configuration of each of the light emitting elements 10R, 10G, and 10B is as described in the First Embodiment.

A sealing film 220 is provided on the light emitting elements 10R, 10G, and 10B. The sealing film 220 is provided to prevent moisture from entering the light emitting elements 10R, 10G, and 10B. An inorganic material such as silicon oxide, silicon nitride, or aluminum oxide, or an organic resin material such as polyimide, polyamide, acrylic, or epoxy can be used for the sealing film 220. FIG. 6 shows a configuration including an inorganic insulating layer 221, an organic insulating layer 222, and an inorganic insulating layer 223 as the sealing film 220.

Although not shown in FIG. 6, a polarizing plate may be provided on the sealing film 220. The polarizing plate may be attached onto the sealing film 220 using an adhesive. Alternatively, the substrate may be attached to the sealing film 220 using an adhesive, and the polarizing plate may be attached to the substrate via the adhesive.

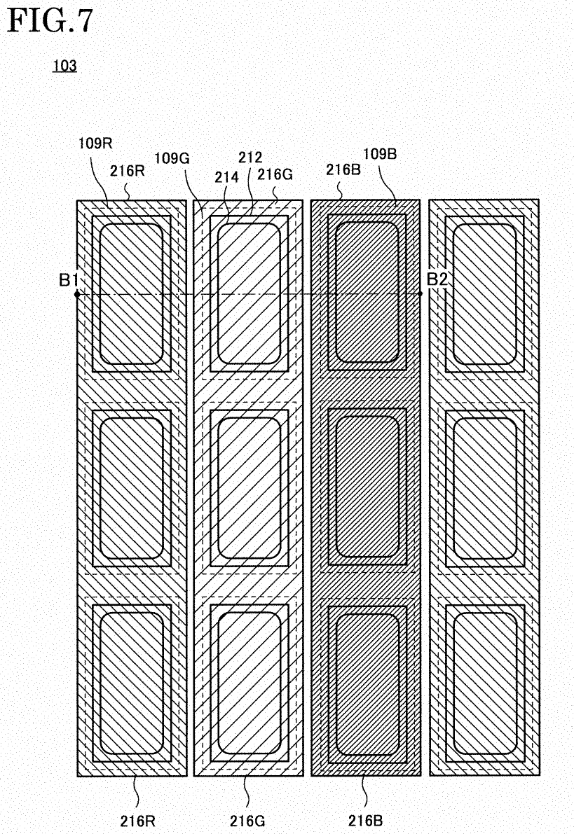

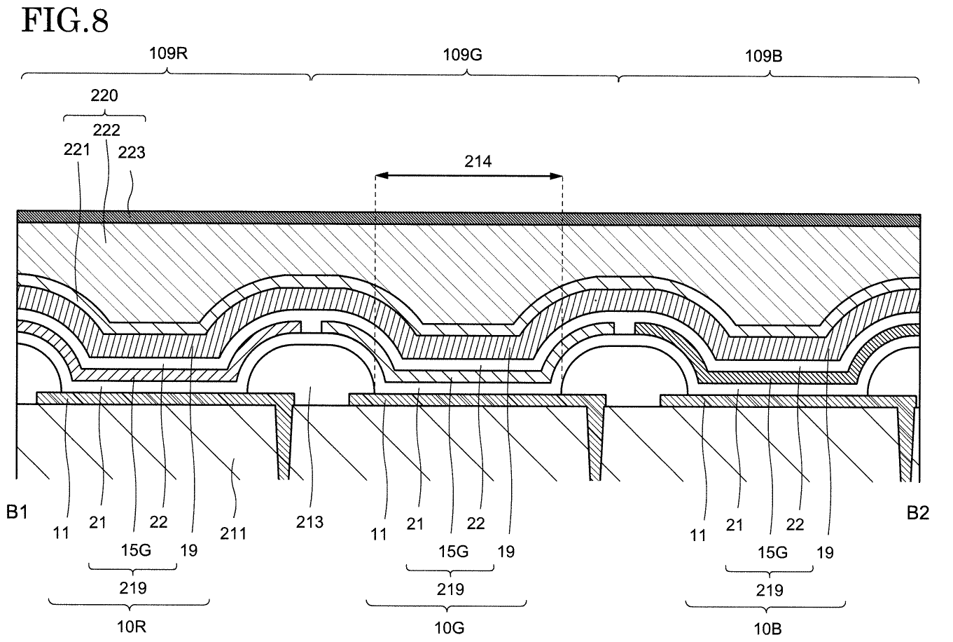

Next, a configuration of the light emitting element included in the pixel of the display device 100 according to the embodiment is described with reference to FIGS. 7 and 8.

FIG. 7 is a plan view showing a layout of the plurality of pixels 109R, 109G, and 109B arranged in a matrix in the display area 103 of the display device 100 according to an embodiment of the invention. Further, FIG. 8 is a cross-sectional view of the display area of the display device 100 according to an embodiment of the present invention. Specifically, FIG. 8 is a cross-sectional view cut along a line B1-B2 shown in FIG. 7. In FIG. 8, cross sections of the light emitting elements 10R, 10G, and 10B provided in pixels 109R, 109G, and 109B, are shown, respectively. Although the cross-section of the transistor 120 connected to each of the light emitting elements 10R, 10G, and 10B is omitted in FIG. 8, the aspect thereof is the same as that described in FIG. 6.

As shown in FIG. 7, in the display area 103, the plurality of pixels 109R, 109G, and 109B are arranged in a matrix. FIG. 8 shows a part of the layers that are included in the pixels 109R, 109G, and 109B. Further, FIG. 8 also shows the first electrode 11, the opening 214 of the bank 213, and the second organic layers 15R, 15G, and 15B. The plurality of first electrodes 11 are arranged in a matrix. The second organic layers 15R, 15G, and 15B are discontinuous between the first electrodes 11 adjacent in the row direction and continuous between the first electrodes 11 adjacent in the column direction.

As described above, in the display device 100 according to the present embodiment, each pixel 109 includes the light emitting element 10, so that the current efficiency and reliability of the display device 100 are improved.

Each of the embodiments described above as an embodiment of the present invention can be appropriately combined and implemented as long as they do not contradict each other. Additions, deletion, or design changes of constituent elements, or additions, omissions, or changes to conditions of steps as appropriate based on the respective embodiments are also included within the scope of the present invention as long as the gist of the present invention is provided.

Other effects which differ from those brought about by each of the embodiments described above, but which are apparent from the description herein or which can be readily predicted by those skilled in the art, are naturally understood to be brought about by the present invention.

What is claimed is:

1. A light emitting element comprising:
a pair of electrodes; and
a first organic layer and a second organic layer adjacent to the first organic layer between the pair of electrodes,
wherein the first organic layer comprises a first organic material,
the second organic layer comprises a second organic material,
the second organic layer comprises a first region and a second region, and
the first region is in contact with the first organic layer and comprises the first organic material.

2. The light emitting element according to claim 1,
wherein the first organic material has a higher hole transport property than an electron transport property, and
an absolute value of a lowest unoccupied molecular orbital (LUMO) level of the first organic layer is smaller than an absolute value of a lowest unoccupied molecular orbital (LUMO) level of the second organic layer.

3. The light emitting element according to claim 2, wherein an absolute value of a difference between the lowest unoccupied molecular orbial (LUMO) level of the first organic layer and the lowest unoccupied molecular orbital (LUMO) level of the second organic layer is greater than or equal to 0.2 eV.

4. The light emitting element according to claim 1, wherein the second organic material has a higher electron transport property than a hole transport property.

5. The light emitting element according to claim 1, wherein a film thickness of the first region is greater than 0% and less than or equal to 40% of a film thickness of the second organic layer.

6. The light emitting element according to claim 1, wherein a concentration of the first organic material in the first region is less than or equal to 20% by weight with respect to the second organic material.

7. The light emitting element according to claim 1, wherein the second region does not comprise the first organic material.

8. The light emitting element according to claim 1,
wherein the second region comprises the first organic material, and
a concentration of the first organic material in the second region is smaller than a concentration of the first organic material in the first region.

9. The light emitting element according to claim 8,
wherein the second organic layer further comprises a third region that is further away from the first organic layer than the second region,
the third region comprises the first material, and
a concentration of the first material in the third region is smaller than the concentration of the first organic material in the second region.

10. The light emitting element according to claim 1, further comprising a third organic layer adjacent to the second organic layer between the pair of electrodes,
wherein the third organic layer comprises a third organic material having a higher electron mobility than a hole mobility, and
an absolute value of a highest occupied molecular orbital (HOMO) level of the third organic layer is larger than an absolute value of a highest occupied molecular orbital (HOMO) level of the second organic layer.

11. The light emitting element according to claim 10, wherein an absolute value of a difference between the highest occupied molecular orbial (LUMO) level of the third organic layer and the highest occupied molecular orbital (LUMO) level of the second organic layer is greater than or equal to 0.2 eV.

12. The light emitting element according to claim 10, wherein the third organic layer is in contact with the second region.

13. The light emitting element according to claim 10,
wherein the second organic layer further comprises a third region that is further away from the first organic layer than the second region and is in contact with the third organic layer,
the third region comprises the first material, and
a concentration of the first material in the third region is smaller than a concentration of the first organic material in the second region.

14. The light emitting element according to claim 1, wherein the second organic layer is a light emitting layer.

15. A display device comprising the light emitting element according to claim 1.
